(19) United States
(12) Patent Application Publication
(10) Pub. No.: US 2013/0192657 A1
(43) Pub. Date: Aug. 1, 2013

(54) Enhanced System and Method for Matrix Panel Ties for Large Installations

(71) Applicant: TIGO ENERGY, INC., Los Gatos, CA (US)

(72) Inventors: Ron Hadar, Cupertino, CA (US); Shmuel Arditi, Los Gatos, CA (US)

(73) Assignee: TIGO ENERGY, INC., Los Gatos, CA (US)

(21) Appl. No.: 13/757,616

(22) Filed: Feb. 1, 2013

Related U.S. Application Data
(60) Provisional application No. 61/593,820, filed on Feb. 1, 2012.

(51) Int. Cl. H01L 31/05

(52) U.S. Cl. CPC H01L 31/0504
USPC 136/244; 438/80

(57) ABSTRACT

A low voltage/power ratio photovoltaic power generation panel includes a plurality of photovoltaic cells, wherein at least a subset of the cells are arranged in an array of “x” columns and “y” rows of cells connected in a two dimensional matrix configuration, wherein the cells in each row are connected in parallel and the cells in each column are connected in series. The cells in the panel are connected by arranging the plurality of cells in a plurality of columns, each column having a number of cells; arranging the plurality of columns in the number of rows; and connecting the plurality of cells together in a two dimensional matrix configuration by connecting the cells in each row together in parallel and the cells in each column in series.

### CROSS REFERENCE TO RELATED APPLICATIONS

This application claims the benefit of priority of U.S. Provisional Patent Application Ser. No. 61/593,820 filed Feb. 1, 2012, which is incorporated herein by reference in its entirety.

### FIELD OF THE TECHNOLOGY

This disclosure relates generally to photovoltaic panel configurations and more particularly to a method and system for interconnection of photovoltaic cells and panels.

### BACKGROUND

In large solar power installations, due to the number of panels required to achieve the desired power, many strings must be connected in parallel. Such an approach increases the system cost by requiring string up-converters, as well as junction boxes or combiner boxes, to combine multiple strings into one feed for an inverter. As the inverters become larger and larger, more strings must be combined.

What is needed is an enhanced system and method to reduce the number of strings that feed into an inverter, thus correspondingly reducing the overall system cost by reducing the amount of additional hardware needed and the labor to install that hardware.

### SUMMARY OF THE DISCLOSURE

An embodiment in accordance with the present disclosure addresses the identified need in a new way. An embodiment in accordance with the present disclosure is a method for connecting a plurality of photovoltaic cells that includes arranging the cells in a two dimensional matrix such that cells in a row have like terminals connected together and cells in each column have negative and positive terminals connected in series. Then a plurality of such matrix connected cell panels are connected together and then connected to an AC grid.

An array in accordance with the present disclosure may include one or more 3 row by 4 column cell matrices or, for example, a series of 6 row by 4 column cell matrices. Two or more matrices may be connected in series or in parallel, depending on the voltage and current requirements. Another embodiment may include a plurality of photovoltaic panels, each panel comprising one or more two dimensional matrices of cells wherein each matrix is connected together in series or in parallel.

An embodiment of a low voltage/power ratio photovoltaic power generation panel may include a plurality of photovoltaic cells, wherein at least a subset of the cells are arranged in an array of “x” columns and “y” rows of cells connected in a two dimensional matrix configuration, wherein the cells in each row are connected in parallel and the cells in each column are connected in series. One embodiment may be configured wherein “x” is at least 3 and “y” is at least 3. Another embodiment may be configured wherein “x” is at least 4 and “y” is at least 3. The panel may include a plurality of two-dimensional matrices of cells connected in series.

An embodiment in accordance with the present disclosure is a method of connecting a plurality of photovoltaic cells together in a panel that includes arranging the plurality of cells in a plurality of columns, each column having a number of cells; arranging the plurality of columns in the number of rows; and connecting the plurality of cells together in a two dimensional matrix configuration by connecting the cells in each row together in parallel and the cells in each column in series. Each cell has a negative terminal and a positive terminal, and the connecting includes for each row of cells electrically joining the negative terminals together and joining the positive terminals together. Preferably the connecting also includes electrically joining the number of rows by joining positive terminals of each row of cells to negative terminals of a next row of the cells.

An embodiment in accordance with the present disclosure is a power generating system that has a plurality of photovoltaic cell panels; each panel containing a plurality of photovoltaic cells connected together in a two dimensional matrix configuration; and an inverter connected between at least one of the panels and an AC power distribution grid.

Another embodiment in accordance with the present disclosure is a photovoltaic power generating system comprising one or more strings of matrices connected cells connected to an inverter and in turn connected to an AC bus without the need for an up-converter.

### BRIEF DESCRIPTION OF THE DRAWING

The embodiments are illustrated by way of example and not limitation in the figures of the accompanying drawings in which like references indicate similar elements.

FIG. 1 is a schematic overview of a series connected solar panel in accordance with the present disclosure.

FIG. 2 is a schematic representation of an exemplary multi-string installation in accordance with the present disclosure.

FIG. 3a is a schematic representation of a 36 cell matrix photovoltaic panel in accordance with the present disclosure.

FIG. 3b is a schematic representation of another 36 cell matrix configuration in a photovoltaic panel in accordance with the present disclosure.

FIG. 4 is an exemplary subsection of the matrix configuration shown in FIG. 3b.

FIG. 5 illustrates a single string of very wide solar panels connected together, wherein each panel includes a matrix connection of cells in accordance with the present disclosure.

### DETAILED DESCRIPTION

The following description and drawings are illustrative and are not to be construed as limiting. Numerous specific details are described to provide a thorough understanding. However, in certain instances, well known or conventional details are not described in order to avoid obscuring the description. References to one or an embodiment in the present disclosure are not necessarily references to the same embodiment; and, such references mean at least one.

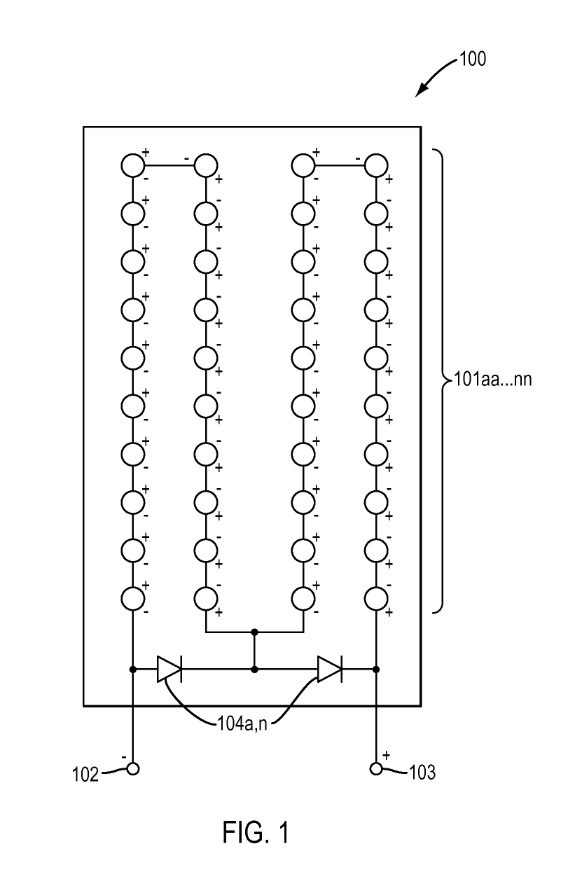

FIG. 1 shows a typical solar panel 100 of the type currently in use. In this example, panel 100 contains 36 solar cells, which number of cells is solely exemplary; a typical panel may contain any of various lesser or greater numbers of cells. Often, the solar cells are connected in one serial string, sometimes divided into two or four sections, with diodes 104a-n. The 36 solar cells 101aa-nn shown in FIG. 1 are, in this example, divided into two sections, which sections are serially connected by string connections 102 and 103.

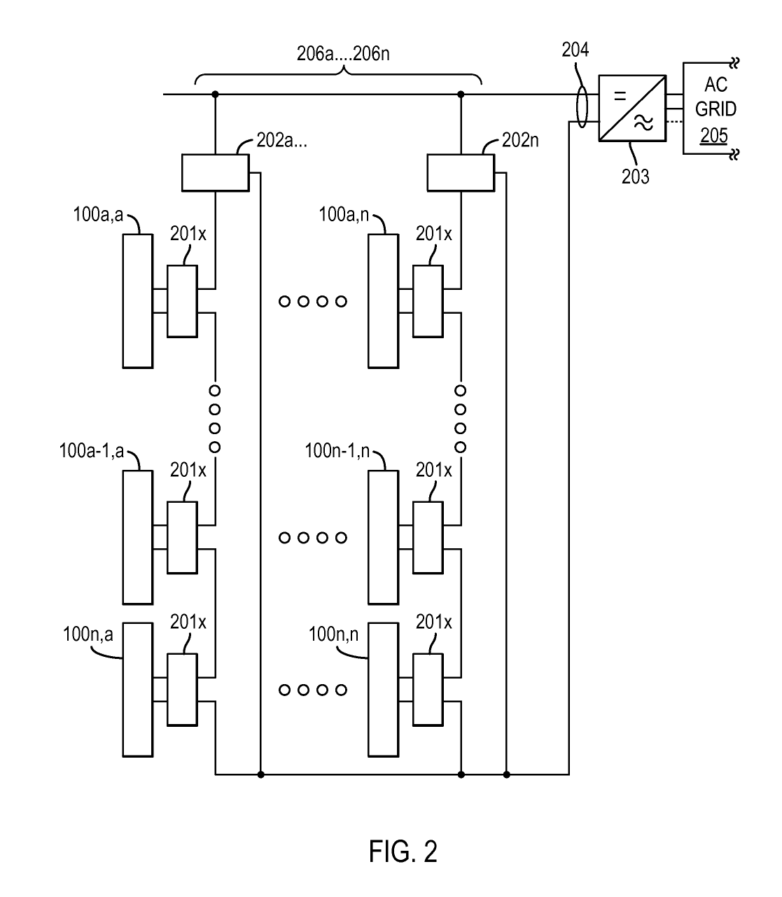

FIG. 2 shows an exemplary multi-string installation 200, in accordance with an embodiment of the present disclosure. Inverter 203 is connected by either two or three phases to ac grid 205. The feed 204 comes by combining multiple strings 206a-n. Each string has a respective up-converter 202a-n, and each panel has a respective LMU 201x connected to panels 100aa-nn. The particular approach of installation 200 is exemplary only, and many variations may be made. For example, there could be combinations of multi-panel LMUs (Local Management Units), reducing the number of LMUs required in the system; also there could be various differing types of up-converters, such as LMU4 or LMU4B as shown and described in our U.S. patent application Ser. No. 13/418,279, filed Mar. 3, 2012, entitled Enhanced System and Method for String Balancing, the content of which is hereby incorporated by reference in its entirety.

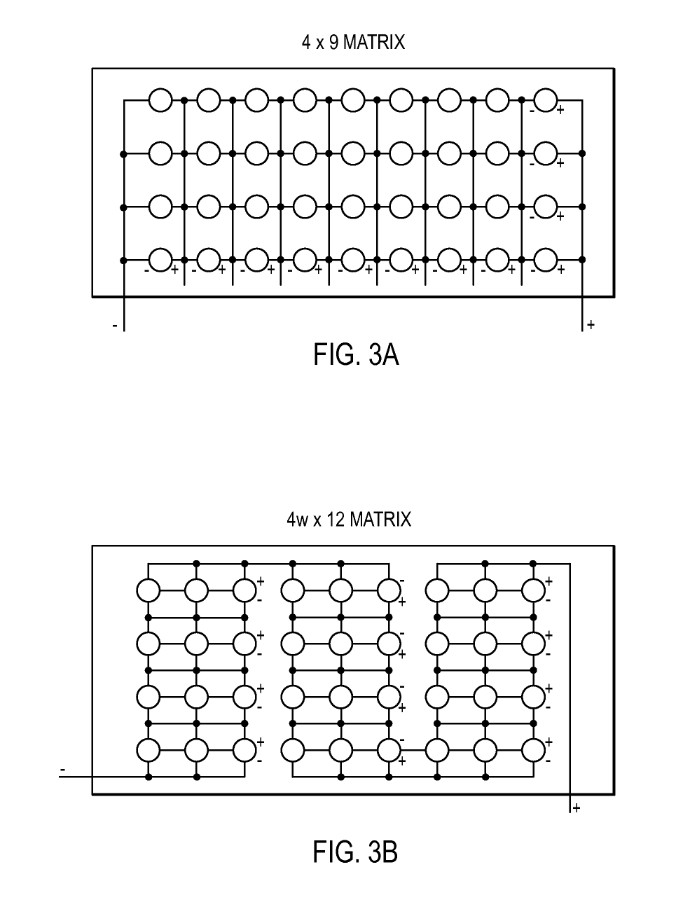

FIG. 3 shows two exemplary panels, according to one aspect of the system and method disclosed herein. FIG. 3a shows a 36-cell matrix, 4 solar cells wide by 9 solar cells long (9 columns, each having 4 cells connected in parallel in a row), the same number of cells in the exemplary panel 100, described in the discussion of FIG. 1. However, in FIG. 3a, the cells are connected in a matrix, which approach has certain advantages to be discussed further below.

FIG. 3b shows another exemplary 36-cell configuration in which three, 3 by 4 matrices of 3 cells in a row and 4 cells in a column are connected in series. In this case the total configuration is 3 cells wide (W) by 12 cells long (serially connected, S), i.e., 12 columns of cross -connected cells, each 3 cells wide. The total number of cells in a matrix is not particularly important; it is notable that using a matrix at least four or five cells wide can improve overall system efficiency, as explained further below.

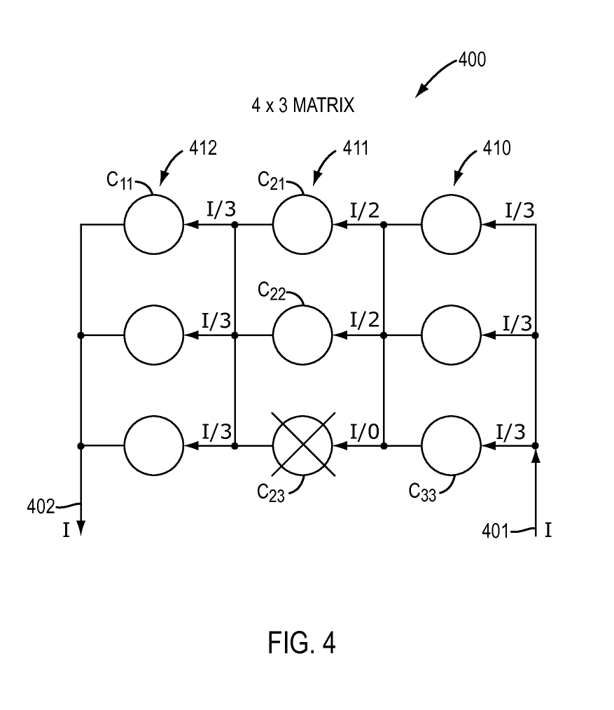

FIG. 4 shows an exemplary subsection 400 of the matrix shown in FIG. 3b. Nine cells, cells C11 to C33 are connected in a 3 column×3 row matrix. Cell C23 has stopped working for some reason, such as, for example, because the cell itself is defective, or because a bird dropping has covered much of its area, or for any other of a variety of reasons. As a result, the current through cell C23 is practically nothing (zero). In this situation, the total current I entering at terminal 401 must be split on each level among the cells. In level 410, the current splits three ways to I/3, one-third on each cell, while in level 411 the current splits only two ways into one-half on each functional cell C21 and C22, because only two cells are active in this level. As a result, the voltage drops as the cells in the affected row are each moved away from its local maximum power production point (MPPT) on the cell level, but in most cases not to zero, and there is a partial loss of power of the total array. Splitting the matrix into sections that are four or five cells wide limits the loss of power in each affected row even further, to around roughly 50 percent (depending on various factors, including but not limited to MPPT of each cell, matching quality between cells in a row, etc.) of the affected row or 5 percent of the total panel (panel/# rows*loss in row=1/9*0.5=˜5.4%).

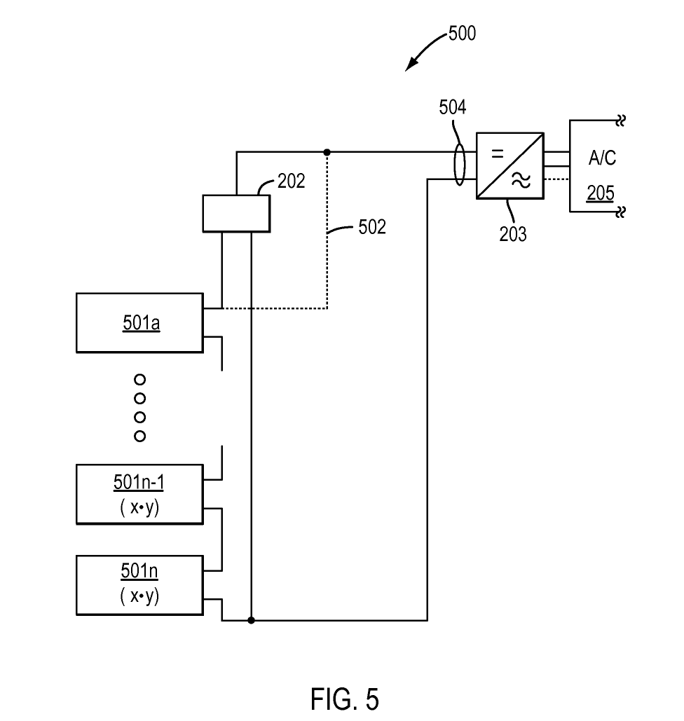

However, because each row in each matrix is only a fraction of the total array, the overall effect is vastly reduced, compared to about 50 percent of the whole panel, as in the case of a series connection as is shown in FIG. 1. This is due to, in part, as in the case of five-wide rows, for example, the current per cell increasing “only” 25 percent, moving the efficiency of that cell to around 40-70 percent. As a result of the vastly reduced loss coming from a bad cell, no local management unit (LMU) is necessary at each panel, but instead, only a string up-converter is required, as shown below in the discussion of FIG. 5.

FIG. 5 shows a single string system 500 of very “wide,” solar panels 501a through 501n connected together in accordance with the present disclosure. The number of panels in a string can be far greater than in current, conventional designs because, in an extreme case, where a panel could be 9 or even 16 cells wide or more and only 4 cells deep, i.e. the panel having a cell matrix of 4 columns with 9 or 16 parallel connected cells in each row, each panel would create only approximately 2 volts, but it would create a very large current. Thus as many as, for example, 300 panels could be connected in one string, in series, and the power from them then fed into the inverter 203.

By matching the voltage operating range of those panel strings through the reduction of losses, with a matrix approach, in many cases no up-converter 202 would actually be needed. In some cases, the string could be connected directly to the inverter 203, as indicated by dotted connection line 502. In other cases an up-converter 202 could still be used, but a single, higher-power version would be sufficient.

Enabling connection of 300 panels in one string as in system 500 can dramatically reduce the number of junction boxes and other components necessary in the photovoltaic power system. Additionally, even though the cables in a system such as disclosed herein need to be of a heavier gauge than the cables in a conventional system, in order to minimize resistive losses, their cost is roughly equivalent to the total cost of the cables in the separate strings of a conventional system, so effectively no additional cost is incurred by using the heavier cables. Furthermore, labor costs will often be lower, as less physical wiring needs to be done. It might be slightly less convenient to install such heavier gauge cables, but this added effort is more than offset by the reduced need to install combiner boxes. Even more cost savings are realized because the system and method disclosed herein does not require LMUs at each panel. The various cost savings described above, overall, makes the system and method disclosed herein highly cost efficient for large installations.

In the foregoing specification, the disclosure has been described with reference to specific exemplary embodiments thereof. It is clear that many modifications and variations of the system and method disclosed herein may be made by one skilled in the art without departing from the spirit of the novel art of this disclosure. These modifications and variations do not depart from its broader spirit and scope as set forth in the following claims.

What is claimed is:

1. A low voltage/power ratio photovoltaic power generation panel comprising:
a plurality of photovoltaic cells, wherein at least a subset of the cells are arranged in an array of “x” columns and “y” rows of cells connected in a two dimensional matrix configuration, wherein the cells in each row are connected in parallel and the cells in each column are connected in series.

2. The panel according to claim 1 wherein “x” is at least 3 and “y” is at least 3.

3. The panel according to claim 1 wherein “x” is at least 4 and “y” is at least 3.

4. The panel according to claim 1 wherein the panel includes a plurality of two dimensional matrices of cells connected in series.

5. A method of connecting a plurality of photovoltaic cells together in a panel comprising:
arranging the plurality of cells in a plurality of columns, each column having a number of cells;
arranging the plurality of columns in the number of rows; and
connecting the plurality of cells together in a two dimensional matrix configuration by connecting the cells in each row together in parallel and the cells in each column in series.

6. The method of claim 5 wherein each cell has a negative terminal and a positive terminal, and the connecting includes for each row of cells electrically joining the negative terminals together and joining the positive terminals together.

7. The method of claim 6 wherein the connecting includes electrically joining the number of rows by joining positive terminals of each row of cells to negative terminals of a next row of the cells.

8. A power generating system comprising:
a plurality of photovoltaic cell panels;
each panel containing a plurality of photovoltaic cells connected together in a two dimensional matrix configuration; and
an inverter connected between at least one of the panels and an AC power distribution grid.

9. The system according to claim 8 wherein the panels are connected to the inverter without an up-converter therebetween.

10. The system of claim 8 wherein each panel comprises:
a plurality of photovoltaic cells, wherein at least a subset of the cells are arranged in an array of “x” columns and “y” rows of cells connected in the two dimensional matrix configuration, wherein the cells in each row are connected in parallel and the cells in each column are connected in series.

11. The system according to claim 10 wherein “x” is at least 3 and “y” is at least 3.

12. The system according to claim 10 wherein “x” is at least 4 and “y” is at least 3.

13. The system according to claim 10 wherein each panel includes a plurality of two dimensional matrices of cells connected in series.
